(19) United States
(12) Patent Application Publication
(10) Pub. No.: US 2026/0198263 A1
(43) Pub. Date: Jul. 9, 2026

(54) SYSTEM FOR ASSEMBLING COMPONENTS OF SUBSTRATE PROCESSING APPARATUS AND METHOD FOR ASSEMBLING COMPONENTS OF SUBSTRATE PROCESSING APPARATUS

(71) Applicant: Tokyo Electron Limited, Tokyo (JP)

(72) Inventor: Yoshitomo KONTA, Miyagi (JP)

(73) Assignee: Tokyo Electron Limited, Tokyo (JP)

(21) Appl. No.: 19/550,383

(22) Filed: Feb. 26, 2026

Related U.S. Application Data
(63) Continuation of application No. PCT/JP2024/031709, filed on Sep. 4, 2024.

(30) Foreign Application Priority Data
Sep. 11, 2023 (JP) 2023-146960

(51) Int. Cl. H10P 72/50; H10P 72/30

(52) U.S. Cl. CPC H10P 72/53; H10P 72/3302; H10P 72/3306

(57) ABSTRACT

In a system for mounting a component on a substrate processing apparatus, a robot transfers the component to a specified position in the apparatus. An image sensor obtains an image of the component and an upper surface of a substrate support in the apparatus. A measurer acquires, based on the image, at least four distances by determining a distance between each of at least two measurement points on the component and each of at least two reference points on the upper surface. A controller causes the robot to transfer the component to the specified position based on a result of comparison of each of the at least four distances with a corresponding one of at least four predetermined reference distances. The at least four predetermined reference distances are the at least four distances in case where the component is placed at the specified position.

### CROSS-REFERENCE TO RELATED APPLICATIONS

This application is a continuation application of PCT Application No. PCT/JP 2024/031709, filed on Sep. 4, 2024, which claims the benefit of priority from Japanese Patent Application No. 2023-146960, filed on Sep. 11, 2023. The entire contents of the above listed PCT and priority applications are incorporated herein by reference.

### FIELD

Exemplary embodiments of the present disclosure relate to a system for mounting a component of a substrate processing apparatus on the substrate processing apparatus and a method for mounting a component of a substrate processing apparatus on the substrate processing apparatus.

### BACKGROUND

Substrate processing apparatuses are used for semiconductor manufacturing. Patent Literature 1 below describes a plasma processing apparatus as a type of a substrate processing apparatus. The substrate processing apparatus includes multiple components. Each component is typically mounted on the substrate processing apparatus using a positioning pin or a fixture or using both.

### CITATION LIST

### Patent Literature

Patent Literature 1: Japanese Unexamined Patent Application Publication No. 2020-191351

### BRIEF SUMMARY

### Technical Problem

One or more aspects of the present disclosure are directed to a technique for mounting a component of a substrate processing apparatus on the substrate processing apparatus with high accuracy and high reproducibility.

### Solution to Problem

A system for mounting a component of a substrate processing apparatus on the substrate processing apparatus according to one exemplary embodiment includes a robot, an image sensor, a measurer, and a controller. The robot transfers the component to a specified position in the substrate processing apparatus. The image sensor obtains an image of the component and an upper surface of a substrate support in the substrate processing apparatus. The measurer calculates, based on the image obtained by the image sensor, at least four distances each between a measurement point of at least two measurement points on the component and a reference point of at least two reference points on the upper surface of the substrate support. The controller controls the robot and causes the robot to transfer the component to the specified position based on a result of comparison of each of the at least four distances calculated by the measurer with a corresponding reference distance of at least four reference distances. Each of the at least four reference distances is a predetermined distance between a measurement point of the at least two measurement points on the component at the specified position and a reference point of the at least two reference points on the upper surface of the substrate support.

### Advantageous Effects

The technique according to one exemplary embodiment can mount a component of a substrate processing apparatus on the substrate processing apparatus with high accuracy and high reproducibility.

### BRIEF DESCRIPTION OF DRAWINGS

FIG. 1 is a block diagram of a system for mounting a component of a substrate processing apparatus on the substrate processing apparatus according to one exemplary embodiment.

FIG. 2 is a schematic diagram of the substrate processing apparatus according to the exemplary embodiment.

FIG. 3 is a perspective view of the system for mounting according to the exemplary embodiment.

FIG. 4 is a diagram showing multiple distances identified in the system for mounting according to the exemplary embodiment.

FIG. 5 is a flowchart of a method for mounting a component of the substrate processing apparatus on the substrate processing apparatus according to the exemplary embodiment.

### DETAILED DESCRIPTION

Various exemplary embodiments will be described below in detail with reference to the drawings. In the figures, like reference numerals denote like or corresponding components.

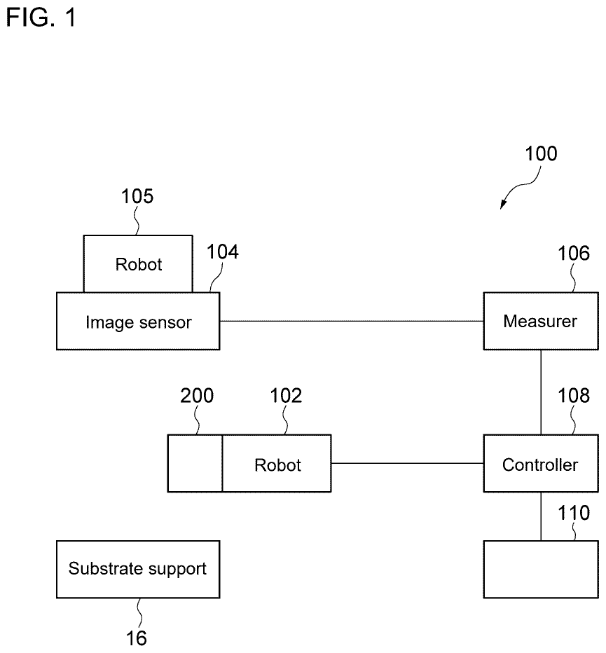

FIG. 1 is a block diagram of a system for mounting a component of a substrate processing apparatus on the substrate processing apparatus according to one exemplary embodiment. The system for mounting shown in FIG. 1 (hereafter referred to as a system 100) includes a robot 102, an image sensor 104, a measurer 106, and a controller 108. The system 100 may further include a robot 105. The system 100 mounts a component of the substrate processing apparatus on the substrate processing apparatus using the robot 102.

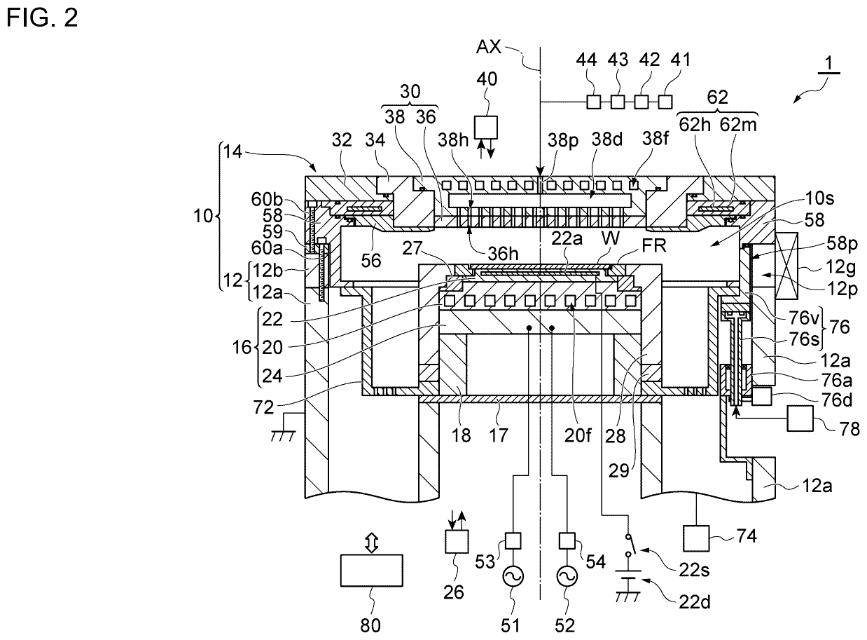

FIG. 2 is a schematic diagram of the substrate processing apparatus according to the exemplary embodiment. In one embodiment, the system 100 may be used to mount a component of a plasma processing apparatus 1 shown in FIG. 2 as the substrate processing apparatus. The system 100 may be used to mount a component of a substrate processing apparatus different from the plasma processing apparatus 1.

As shown in FIG. 2, the plasma processing apparatus 1 includes a chamber 10. The chamber 10 has an internal space 10s. The internal space 10s is pressure-reducible. A plasma is generated in the internal space 10s.

In one embodiment, the chamber 10 may include a chamber body 12 and a ceiling 14. The chamber body 12 defines the sidewall and the bottom of the chamber 10. The chamber body 12 is substantially cylindrical. The chamber body 12 has its central axis substantially aligned with an axis AX extending in the vertical direction. The chamber body 12 is electrically grounded. The chamber body 12 is formed from, for example, aluminum. The chamber body 12 has an anticorrosive film on its surface. The anticorrosive film is formed from a material such as aluminum oxide or yttrium oxide.

The chamber 10 has an opening 12p in its sidewall. The opening 12p is defined by the chamber body 12. The opening 12 p is opened and closed by a gate valve 12g. A substrate W is transferred between the internal space 10s and the outside of the chamber 10 through the opening 12p.

In one embodiment, the chamber body 12 includes a first member 12a and a second member 12b. The first member 12a is substantially cylindrical. The first member 12a defines the bottom and a part of the sidewall of the chamber 10. The second member 12b is substantially cylindrical. The second member 12b is located on the first member 12a. The second member 12b defines another part of the sidewall of the chamber 10. The second member 12b defines the opening 12p.

The plasma processing apparatus 1 further includes a substrate support 16. The substrate support 16 is located in the internal space 10s. The substrate support 16 supports the substrate W placed on its upper surface. A bottom plate 17 is located under the substrate support 16. The bottom plate 17 is supported by the bottom of the chamber 10, or for example, the first member 12a. A support member 18 extends upward from the bottom plate 17. The support member 18 is substantially cylindrical. The support member 18 is formed from an insulator such as quartz. The substrate support 16 is located on and supported by the support member 18.

The substrate support 16 includes a base 20 and an electrostatic chuck (ESC) 22. The substrate support 16 may further include an electrode plate 24. The electrode plate 24 is substantially disk-shaped. The electrode plate 24 has its central axis substantially aligned with the axis AX. The electrode plate 24 is formed from a conductor such as aluminum.

The base 20 is located on the electrode plate 24. The base 20 is electrically coupled to the electrode plate 24. The base 20 is substantially disk-shaped. The base 20 has its central axis substantially aligned with the axis AX. The base 20 is formed from a conductor such as aluminum. The base 20 includes a channel 20f inside. The channel 20f extends, for example, spirally. The channel 20f receives a refrigerant from a chiller unit 26. The chiller unit 26 is located outside the chamber 10. The chiller unit 26 supplies, for example, a liquid refrigerant to the channel 20f. The refrigerant supplied to the channel 20f returns to the chiller unit 26.

The ESC 22 is located on the base 20. The ESC 22 includes a body and an electrode 22a. The body of the ESC 22 is substantially disk-shaped. The ESC 22 and its body have the central axis aligned with the axis AX. The body of the ESC 22 is formed from ceramic. The electrode 22a is a film formed from a conductor. The electrode 22a is located inside the body of the ESC 22. The electrode 22a is coupled to a DC power supply 22d through a switch 22s. To cause the ESC 22 to hold the substrate W, a voltage from the DC power supply 22d is applied to the electrode 22a. A voltage applied to the electrode 22a generates an electrostatic attraction between the ESC 22 and the substrate W. The electrostatic attraction causes the ESC 22 to attract and hold the substrate W. The plasma processing apparatus 1 may have a gas line to supply a heat transfer gas (e.g., a helium gas) to a space between the ESC 22 and the back surface of the substrate W.

An edge ring FR is placed on the periphery of the ESC 22 to surround the substrate W. The edge ring FR is used to improve the uniformity of the plasma processing across the surface of the substrate W. The edge ring FR is formed from, for example, silicon, quartz, or silicon carbide. A ring 27 is located between the edge ring FR and the base 20. The ring 27 is formed from an insulator.

In one embodiment, the plasma processing apparatus 1 may further include a cylindrical portion 28 and a cylindrical portion 29. The cylindrical portion 28 extends along the outer peripheries of the substrate support 16 and the support member 18. The cylindrical portion 28 is located on the cylindrical portion 29. The cylindrical portion 28 is formed from an anticorrosive insulator. The cylindrical portion 28 is formed from, for example, quartz. The cylindrical portion 29 extends along the outer periphery of the support member 18. The cylindrical portion 29 is formed from an anticorrosive insulator. The cylindrical portion 29 is formed from, for example, quartz.

The ceiling 14 closes the opening of the chamber 10 at the upper end. The ceiling 14 includes an upper electrode 30. The ceiling 14 may further include a member 32 and a member 34. The member 32 is a substantially annular plate formed from a metal such as aluminum. The member 32 is located on the sidewall of the chamber 10 with a wall member 58 (described later) between the member 32 and the sidewall. The member 34 is located between the upper electrode 30 and the member 32. The member 34 extends in the circumferential direction about the axis AX. The member 34 is formed from an insulator such as quartz. A sealing member such as an O-ring is located between the upper electrode 30 and the member 34. A sealing member such as an O-ring is located between the member 34 and the member 32.

The upper electrode 30 includes a ceiling plate 36 and a support member 38. The ceiling plate 36 is substantially disk-shaped. The ceiling plate 36 faces the internal space 10s. The ceiling plate 36 has multiple gas outlets 36h. The gas outlets 36h extend through the ceiling plate 36 in the thickness direction (vertical direction). The ceiling plate 36 is formed from silicon, aluminum oxide, or quartz. In some embodiments, the ceiling plate 36 may be a conductor such as aluminum with an anticorrosive film on its surface. The anticorrosive film is formed from a material such as aluminum oxide or yttrium oxide.

The support member 38 is located on the ceiling plate 36. The support member 38 supports the ceiling plate 36 in a detachable manner. The support member 38 is formed from, for example, aluminum. The support member 38 includes a channel 38f. The channel 38f extends, for example, spirally inside the support member 38. The channel 38f receives a refrigerant from a chiller unit 40. The chiller unit 40 is located outside the chamber 10. The chiller unit 40 supplies a liquid refrigerant (e.g., cooling water) to the channel 38f. The refrigerant supplied to the channel 38f returns to the chiller unit 40. The chiller unit 40 may supply the refrigerant to the channel 38 f at a flow rate of, for example, 4 L/min or greater.

The support member 38 includes a gas-diffusion compartment 38d inside. The support member 38 has multiple holes 38h. The holes 38h extend downward from the gas-diffusion compartment 38d and connect with the respective gas outlets 36h. The support member 38 includes a port 38p. The port 38p connects with the gas-diffusion compartment 38d. The port 38p is connected to a gas source set 41 through a valve set 42, a flow controller set 43, and a valve set 44.

The gas source set 41 includes multiple gas sources. Each of the valve set 42 and the valve set 44 includes multiple valves. The flow controller set 43 includes multiple flow controllers. Each flow controller is a mass flow controller or a pressure-based flow controller. Each gas source in the gas source set 41 is connected to the port 38p through the corresponding valve in the valve set 42, the corresponding flow controller in the flow controller set 43, and the corresponding valve in the valve set 44. In the plasma processing apparatus 1, one or more gas sources selected from the gas sources in the gas source set 41 supply a gas to the gas-diffusion compartment 38d. The gas is then supplied from the gas-diffusion compartment 38d to the internal space 10s through the gas outlets 36h.

The plasma processing apparatus 1 further includes a radio-frequency (RF) power supply 51 and a bias power supply 52. The RF power supply 51 generates source RF power for generating a plasma from the gas in the chamber 10. The source RF power has a frequency of, for example, 27 MHz or higher. The RF power supply 51 is coupled to an RF electrode through a matcher 53. The RF electrode is an electrode (e.g., the base 20) in the substrate support 16 or the upper electrode 30. The matcher 53 includes a matching circuit for matching the impedance of a load on the RF power supply 51 with the output impedance of the RF power supply 51.

The bias power supply 52 generates an electrical bias to draw ions toward the substrate W. The electrical bias has a bias frequency. The bias frequency is, for example, 13.56 MHz or lower. The electrical bias may be bias RF power having the bias frequency. In this case, the bias power supply 52 is electrically coupled to a bias electrode (e.g., the base 20) in the substrate support 16 through a matcher 54. The matcher 54 includes a matching circuit for matching the impedance of a load on the bias power supply 52 with the output impedance of the bias power supply 52. In some embodiments, the electrical bias may be voltage pulses cyclically generated at an interval that is the inverse of the bias frequency. In this case, the bias power supply 52 is coupled to the bias electrode without being through the matcher 54.

The plasma processing apparatus 1 further includes the wall member 58. The wall member 58 is partially located in the internal space 10s. In other words, a part of the wall member 58 is exposed to the plasma in the internal space 10s. The wall member 58 extends from the internal space 10s to the outside of the chamber 10 and is exposed to the space outside the chamber 10.

In one embodiment, the wall member 58 extends along the inner wall surface of the chamber 10 to reduce by-product from plasma processing depositing on the inner wall surface of the chamber 10. More specifically, the wall member 58 extends along the inner wall surface of the chamber body 12 or the inner wall surface of the second member 12b. The wall member 58 is substantially cylindrical. The wall member 58 may be a conductor such as aluminum with an anticorrosive film on its surface. The anticorrosive film is formed from a material such as aluminum oxide or yttrium oxide. The wall member 58 is grounded and is at a ground potential.

In one embodiment, the wall member 58 is held between the chamber body 12 and the ceiling 14. For example, the wall member 58 is held between the second member 12b in the chamber body 12 and the member 32 in the ceiling 14.

In one embodiment, the plasma processing apparatus 1 may further include a spacer 59. The spacer 59 is a plate extending in the circumferential direction about the axis AX. The spacer 59 is located between the wall member 58 and the chamber 10. The spacer 59 is formed from, for example, a conductor. The spacer 59 may be formed from a material having a lower thermal conductivity than aluminum. The spacer 59 may be formed from, for example, stainless steel. The spacer 59 may be formed from any material, other than stainless steel, having a lower thermal conductivity than aluminum. The spacer 59 may be formed from aluminum.

In one embodiment, the spacer 59 is located between the wall member 58 and the second member 12b. In one embodiment, the spacer 59 and the second member 12b are fastened to the first member 12a with a screw 60a. The screw 60a extends through the spacer 59 and the second member 12b and is screwed in a threaded hole in the first member 12a. The wall member 58 is fastened to the spacer 59 with a screw 60b. The screw 60b extends through the wall member 58 and is screwed in a threaded hole in the spacer 59. In this embodiment, the spacer 59 and the second member 12b remain fastened to the first member 12a with the screw 60a when the wall member 58 is removed from the chamber 10 for, for example, maintenance of the wall member 58. This allows the wall member 58 to be removed from the chamber 10 with the spacer 59 and the second member 12b remaining fastened.

In one embodiment, the plasma processing apparatus 1 further includes a heater unit 62. The heater unit 62 includes a body 62m and a heater 62 h. The heater 62 h heats the wall member 58. The heater 62h may be a resistance heating element. The heater 62h is located inside the body 62m . The body 62m is in thermal contact with the wall member 58. In one embodiment, the body 62m is in physical contact with the wall member 58. The body 62m is formed from a conductor such as aluminum. The heater 62h heats the wall member 58 through the body 62m . In one embodiment, the body 62m is a substantially annular plate extending in the circumferential direction to surround the upper electrode 30.

The plasma processing apparatus 1 further includes a ground member 56. The ground member 56 may define a part of the ceiling 14. The ground member 56 is formed from silicon (e.g., polycrystalline silicon). The ground member 56 is located in the internal space 10s, or specifically, in the space in which a plasma is generated. The ground member 56 is grounded. The ground member 56 is at a ground potential, as is the wall member 58.

In one embodiment, the ground member 56 is a substantially annular plate. The ground member 56 extends in the circumferential direction in an area outward from the ceiling plate 36 in the radial direction. The radial direction is the direction that is radial from the axis AX. The heater unit 62 is located between the ground member 56 and the member 32 and between the member 34 and the wall member 58.

Sealing members such as O-rings are located between the body 62m and members adjacent to the body 62m to separate a reduced pressure environment including the internal space 10s from an atmospheric pressure environment. More specifically, a sealing member is located between the body 62m and the member 32. A sealing member is also located between the body 62m and the wall member 58.

In one embodiment, a baffle 72 having multiple through-holes is located between the wall member 58 and the support member 18. In one embodiment, the baffle 72 is substantially cylindrical. The baffle 72 has an upper end with a flange. The baffle 72 has a lower end substantially annular and extending inward in the radial direction. The baffle 72 has, at the upper end, an outer edge connected to the lower end of the wall member 58. The baffle 72 has, at the lower end, an inner edge held between the cylindrical portion 29 and the bottom plate 17. The baffle 72 is formed from a plate of a conductor such as aluminum. The baffle 72 has an anticorrosive film on its surface. The anticorrosive film is formed from a material such as aluminum oxide or yttrium oxide. The baffle 72 has multiple through-holes.

The internal space 10s includes an exhaust area extending below the baffle 72. The exhaust area is connected to an exhaust device 74. The exhaust device 74 includes a pressure regulator such as an automatic pressure control valve and a vacuum pump such as a turbomolecular pump.

The wall member 58 has an opening 58p. The opening 58p in the wall member 58 faces the opening 12p. The substrate W is transferred between the internal space 10s and the outside of the chamber 10 through the opening 12p and the opening 58p.

In one embodiment, the plasma processing apparatus 1 may further include a shutter 76. The shutter 76 opens and closes the opening 58p. The shutter 76 includes a valve element 76v and a shaft 76s. The shutter 76 may further include a tubular member 76a and a drive 76d.

When placed in the opening 58p, the valve element 76v closes the opening 58p. The valve element 76v is supported by the shaft 76s. In other words, the shaft 76s is connected to the valve element 76v. The shaft 76s extends downward from the valve element 76v. The shaft 76s is substantially cylindrical. The shaft 76s may include a heater in its upper end portion. The heater heats the valve element 76v.

The tubular member 76a is cylindrical. The tubular member 76a is fixed to the chamber body 12 directly or indirectly. The shaft 76s is vertically movable through the tubular member 76a. The drive 76d generates power for moving the shaft 76s vertically. The drive 76d includes, for example, a motor. The tubular member 76a includes a seal between the tubular member 76a and the shaft 76s. The seal may be, but not limited to, an O-ring or a magnetic fluid seal. A space between the tubular member 76a and the chamber body 12 is closed by a wall for maintaining airtightness of the internal space 10s.

In one embodiment, the plasma processing apparatus 1 may further include a feeder 78. The feeder 78 feeds a refrigerant to a hollow in the shaft 76s. The refrigerant is, for example, air, cooling air, or an inert gas. The refrigerant is fed into the shaft 76s in the shutter 76 to indirectly cool the valve element 76v. The valve element 76v can thus be cooled indirectly without being directly exposed to the refrigerant.

In one embodiment, the plasma processing apparatus 1 may further include a controller 80. The controller 80 controls each component of the plasma processing apparatus 1. The controller 80 is, for example, a computer. The controller 80 includes a processor, a storage, an input device such as a keyboard, a display, and an input-output interface through which signals are received and transmitted. The storage stores a control program and recipe data. The processor executes the control program and transmits a control signal to each component of the plasma processing apparatus 1 through the input-output interface based on the recipe data.

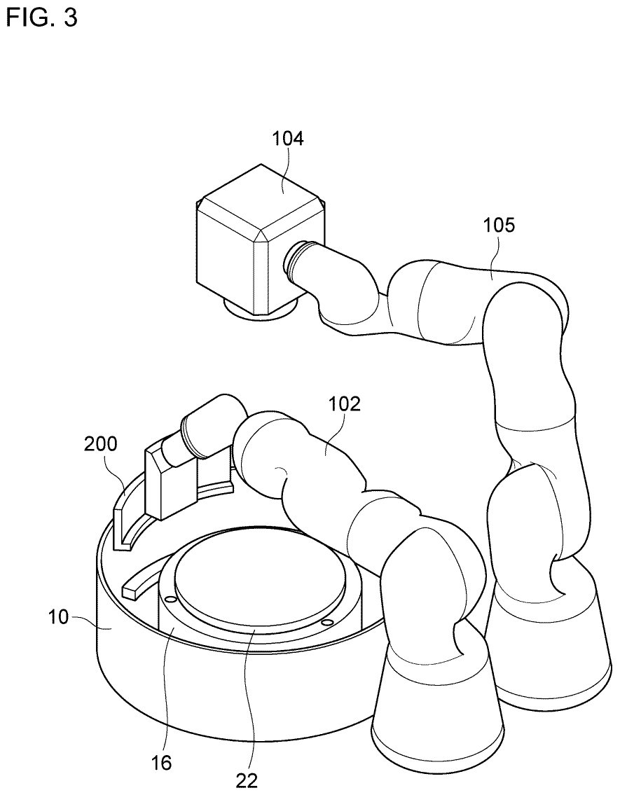

The system 100 will now be described in detail with reference to FIG. 3 in addition to FIGS. 1 and 2. FIG. 3 is a perspective view of the system for mounting according to the exemplary embodiment. In the system 100, the robot 102 transfers a component 200 of the substrate processing apparatus to a specified position in the substrate processing apparatus. The robot 102 may include a robotic arm that is, for example, an articulated arm. The robot 102 is controlled by the controller 108. The robot 102 includes a handler at the distal end of the arm. The component 200 is supported or held by the handler while being transferred. The component 200 transferred by the robot 102 may be, for example, the valve element 76v described above. The component 200 transferred by the robot 102 may be at least one of the baffle 72, the ground member 56, or the wall member 58.

The image sensor 104 obtains an image of the component 200 and the upper surface of the substrate support 16 (the upper surface of the ESC 22). The image sensor 104 may be located above the substrate processing apparatus. The position of the image sensor 104 may be fixed. In some embodiments, the image sensor 104 may be movable. For example, the image sensor 104 may be held by the robot 105 to be movable. The robot 105 may be controlled by the controller 108.

The image sensor 104 may obtain an image of the component 200 and the upper surface of the substrate support 16 (the upper surface of the ESC 22) as a single image. In some embodiments, the image sensor 104 may separately obtain an image of the component 200 and an image of the upper surface of the substrate support 16. In this case, the image sensor 104 may be moved by the robot 105 to separately obtain an image of the component 200 and an image of the upper surface of the substrate support 16. The image obtained by the image sensor 104 is input into the measurer 106.

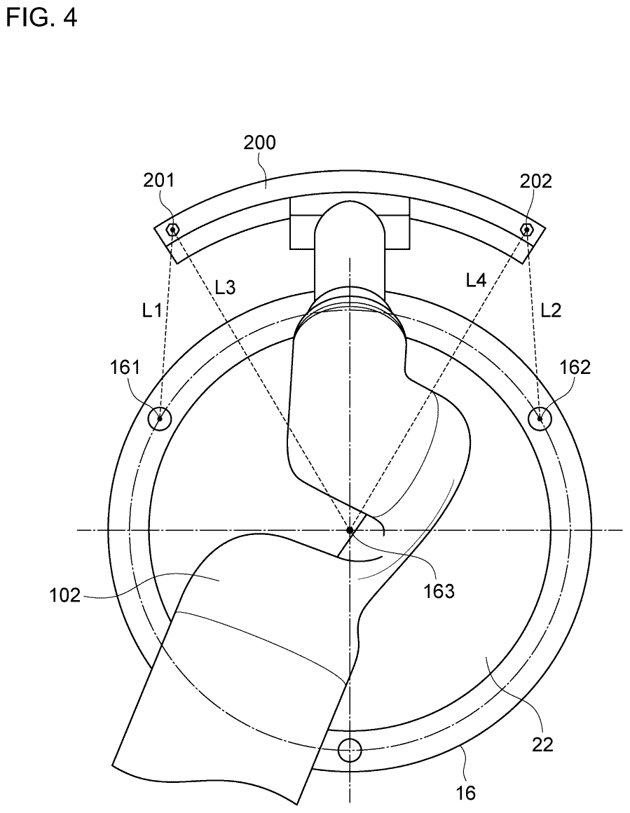

FIG. 4 will now be referred to in addition to FIGS. 1 to 3. FIG. 4 is a diagram showing multiple distances identified in the system for mounting according to the exemplary embodiment. The measurer 106 calculates, based on the image obtained by the image sensor 104, at least four distances each between a measurement point of at least two measurement points on the component 200 and a reference point of at least two reference points on the upper surface of the substrate support 16. The measurer 106 may be a computing device such as a computer. The measurer 106 may be a computing device that also serves as the controller 108. In some embodiments, the measurer 106 may be a computing device separate from the controller 108. The measurer 106 may be a dedicated circuit.

The at least two reference points on the upper surface of the substrate support 16 can be identified by the measurer 106 based on the image of the upper surface of the substrate support 16 obtained by the image sensor 104. One or more of the at least two reference points on the upper surface of the substrate support 16 may be points (e.g., the center points) in markers on the upper surface of the substrate support 16. The markers on the upper surface of the substrate support 16 may be, but not limited to, a pattern identifiable through image recognition, such as threaded holes included in the upper surface of the substrate support 16.

In the example shown in FIG. 4, the at least two reference points include reference points 161 to 163 (first to third reference points). The reference point 161 and the reference point 162 may be identified by the measurer 106 through image recognition of the markers on the upper surface of the substrate support 16. The reference point 161 and the reference point 162 may be located on a circle having the center point aligned with the center point of the upper surface of the substrate support 16, or specifically, the intersection between the upper surface of the substrate support 16 and the axis AX aligned with the central axis of the substrate support 16. In this case, the reference point 163 may be identified as the above center point of the circle identified based on the reference points 161 and 162 by the measurer 106. In some embodiments, all the reference points 161 to 163 may be identified through image recognition of the markers on the upper surface of the substrate support 16.

The at least two measurement points on the component 200 can also be identified by the measurer 106 based on the image of the component 200 obtained by the image sensor 104. Each of the at least two measurement points on the component 200 may be a point (e.g., the center point) in a marker on the component 200. In the example shown in FIG. 4, the at least two measurement points include measurement points 201 and 202.

The measurer 106 calculates at least two distances for each of the at least two measurement points, or in other words, the distances from each measurement point to the corresponding reference points of the at least two reference points on the upper surface of the substrate support 16. The measurer 106 thus calculates at least four distances described above.

In one embodiment, the measurer 106 may calculate a distance L1 (first distance) between the measurement point 201 (first measurement point) and the reference point 161 (first reference point). The measurer 106 may further calculate a distance L2 (second distance) between the measurement point 202 (second measurement point) and the reference point 162 (second reference point). The measurer 106 may further calculate a distance L3 (third distance) between the measurement point 201 (first measurement point) and the reference point 163 (third reference point). The measurer 106 may further calculate a distance L4 (fourth distance) between the measurement point 202 (second measurement point) and the reference point 163 (third reference point). In some embodiments, the measurer 106 may calculate the distance between the measurement point 201 and the reference point 162 as the distance L3, and may calculate the distance between the measurement point 202 and the reference point 161 as the distance L4. In this case, the reference point 163 is not identified. The reference point 161, the reference point 162, the reference point 163, the measurement point 201, and the measurement point 202 may be set to cause the distance L1 and the distance L2 to be equal to each other and cause the distance L3 and the distance L4 to be equal to each other with the component 200 at the specified position.

The controller 108 controls the robot 102 and causes the robot 102 to transfer the component 200 to the specified position. As described above, the controller 108 may control the robot 105 and cause the robot 105 to move the image sensor 104 to obtain an image of the component 200 and the upper surface of the substrate support 16. The controller 108 may be a computing device such as a computer, or may be a dedicated circuit.

The controller 108 controls the robot 102 and causes the robot 102 to transfer the component 200 to the specified position based on the result of comparison of each of the at least four distances (e.g., the distances L1 to L4) calculated by the measurer 106 with the corresponding reference distance of at least four reference distances. The at least four reference distances are the distances with which the controller 108 compares the respective at least four distances calculated by the measurer 106 described above. Each of the at least four reference distances is a predetermined distance between one of the at least two measurement points on the component 200 at the specified position and one of the at least two reference points on the upper surface of the substrate support 16. The at least four reference distances are stored, in a manner associated with identification information of the component 200, into the controller 108 or into an external storage 110 that can be accessed by the controller 108.

The controller 108 controls the transfer position of the component 200 to cause the above result of comparison to satisfy an evaluation criterion. When the result of comparison satisfies the evaluation criterion, the controller 108 controls the robot 102 and causes the robot 102 to fix the position of the component 200 and fix the component 200 in the substrate processing apparatus. In one embodiment, the evaluation criterion may be satisfied when each of the at least four distances matches the corresponding reference distance or when the difference between each of the at least four distances and the corresponding reference distance is within a given error range.

In the system 100, the position of the component 200 is adjusted using at least two reference points on the upper surface of the substrate support 16 in the substrate processing apparatus as absolute standards. The system 100 can thus mount the component 200 on the substrate processing apparatus with high accuracy and high reproducibility. The upper surface of the substrate support 16 is the surface to receive a substrate to be processed in the substrate processing apparatus. The component 200 is thus to be positioned with high accuracy with respect to the upper surface of the substrate support 16 for substrate processing with high accuracy and high reproducibility. To allow substrate processing with high accuracy and high reproducibility, the system 100 can mount the component 200 on the substrate processing apparatus using at least two reference points on the upper surface of the substrate support 16 in the substrate processing apparatus as absolute standards.

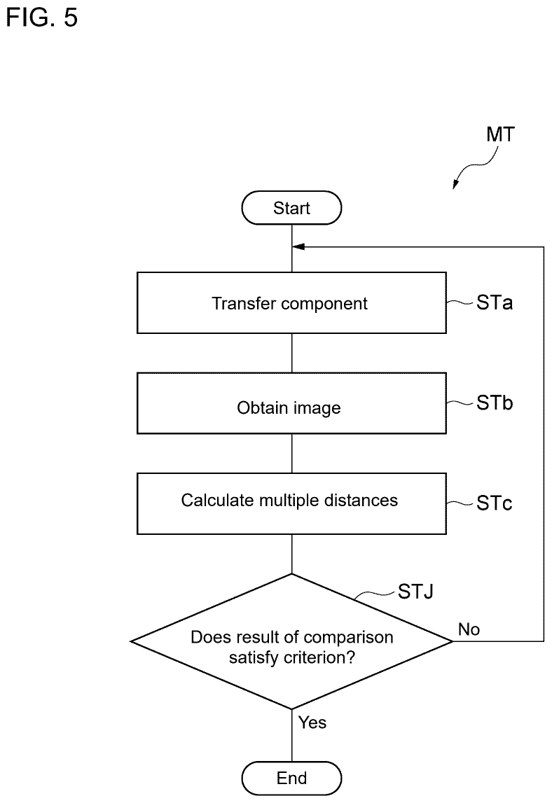

A method for mounting a component of the substrate processing apparatus on the substrate processing apparatus according to an exemplary embodiment will now be described with reference to FIG. 5. FIG. 5 is a flowchart of a method for mounting a component of the substrate processing apparatus on the substrate processing apparatus according to the exemplary embodiment. The method for mounting shown in FIG. 5 (hereafter referred to as a method MT) includes steps STa to STc.

In step STa, the component 200 is transferred by the robot 102 to the specified position in the substrate processing apparatus. The component 200 is transferred by the robot 102 in the manner described above with reference to the system 100.

In step STb, an image of the component 200 and the upper surface of the substrate support 16 in the substrate processing apparatus is obtained by the image sensor 104. The image is obtained by the image sensor 104 in the manner described above with reference to the system 100.

In step STc, at least four distances are calculated by the measurer 106 based on the image obtained by the image sensor 104. Each of the at least four distances is the distance between a measurement point of at least two measurement points on the component 200 and a reference point of at least two reference points on the upper surface of the substrate support 16. The at least four distances are calculated by the measurer 106 in the manner described above with reference to the system 100.

In step STJ, the determination is performed by the controller 108 as to whether the result of comparison of each of the at least four distances calculated by the measurer 106 with the corresponding reference distance of the at least four reference distances described above satisfies the evaluation criterion. When the result of comparison does not satisfy the evaluation criterion, the processing in step STa and the subsequent steps is performed again to cause the robot 102 to be controlled by the controller 108 to transfer the component 200 to the specified position. The transfer position of the component 200 is adjusted until the result of comparison satisfies the evaluation criterion. The robot 102 is controlled by the controller 108 in the manner described above with reference to the system 100.

Although various exemplary embodiments have been described above, the embodiments are not restrictive, and various additions, omissions, substitutions, and changes may be made. The components in the different exemplary embodiments may be combined to form another embodiment.

For example, the number of reference points on the substrate support 16 may be any number greater than or equal to two. The number of measurement points on the component 200 may be any number greater than or equal to two. Multiple reference points for each of multiple components of the substrate processing apparatus may be different from multiple reference points for another one of the components. Thus, at least four reference distances for each of the components may be different from at least four reference distances for another one of the components. The at least four reference distances for each of the components may be stored into the storage 110 in association with identification information of the component.

Various exemplary embodiments E1 to E9 included in the present disclosure will now be described.

### E1

A system for mounting a component of a substrate processing apparatus on the substrate processing apparatus, the system comprising:
a robot configured to transfer the component to a specified position in the substrate processing apparatus;
an image sensor configured to obtain an image of the component and an upper surface of a substrate support in the substrate processing apparatus;
a measurer configured to calculate, based on the image obtained by the image sensor, at least four distances each between a measurement point of at least two measurement points on the component and a reference point of at least two reference points on the upper surface of the substrate support; and
a controller configured to control the robot and cause the robot to transfer the component to the specified position based on a result of comparison of each of the at least four distances calculated by the measurer with a corresponding reference distance of at least four predetermined reference distances each being a distance between a measurement point of the at least two measurement points on the component at the specified position and a reference point of the at least two reference points on the upper surface of the substrate support.

### E2

The system according to E1, wherein
the substrate support includes, as the at least two reference points, a first reference point, a second reference point, and a third reference point, and
the measurer calculates, as the at least four distances, a first distance between a first measurement point of the at least two measurement points and the first reference point, a second distance between a second measurement point of the at least two measurement points and the second reference point, a third distance between the first measurement point and the third reference point, and a fourth distance between the second measurement point and the third reference point.

### E3

The system according to E2, wherein
the first reference point and the second reference point are located on a circle having a center point aligned with a center point of the upper surface of the substrate support, and the first reference point and the second reference point are markers recognizable in the image, and
the measurer identifies, as the third reference point, the center point of the circle identified based on the first reference point and the second reference point.

### E4

The system according to E3, wherein
the first reference point, the second reference point, the third reference point, the first measurement point, and the second measurement point are set to cause the first distance and the second distance to be equal to each other and cause the third distance and the fourth distance to be equal to each other with the component at the specified position.

### E5

The system according to E1, wherein
the substrate support includes, as the at least two reference points, a first reference point and a second reference point, and
the measurer calculates, as the at least four distances, a distance between a first measurement point of the at least two measurement points and the first reference point, a distance between the first measurement point and the second reference point, a distance between a second measurement point of the at least two measurement points and the first reference point, and a distance between the second measurement point and the second reference point.

### E6

The system according to any one of E1 to E5, wherein
the substrate support includes an electrostatic chuck, and
the upper surface of the substrate support is an upper surface of the electrostatic chuck.

### E7

The system according to E6, wherein
the substrate processing apparatus is a plasma processing apparatus including a chamber in which the substrate support is located.

### E8

The system according to any one of E1 to E7, further comprising:
another robot configured to move the image sensor,
wherein the controller controls the other robot and causes the other robot to move the image sensor to obtain the image of the component and the upper surface of the substrate support.
E9

A method for mounting a component of a substrate processing apparatus on the substrate processing apparatus, the method comprising:
(a) transferring, with a robot, the component to a specified position in the substrate processing apparatus;
(b) obtaining, with an image sensor, an image of the component and an upper surface of a substrate support in the substrate processing apparatus; and
(c) calculating, with a measurer, based on the image obtained by the image sensor, at least four distances each between a measurement point of at least two measurement points on the component and a reference point of at least two reference points on the upper surface of the substrate support,
wherein (a) includes controlling, with a controller, the robot and causing the robot to transfer the component to the specified position based on a result of comparison of each of the at least four distances calculated by the measurer with a corresponding reference distance of at least four predetermined reference distances each being a distance between a measurement point of the at least two measurement points on the component at the specified position and a reference point of the at least two reference points on the upper surface of the substrate support.

Various exemplary embodiments according to the present disclosure have been described by way of example, and various changes may be made without departing from the scope and spirit of the present disclosure. The exemplary embodiments described above are thus not restrictive, and the true scope and spirit of the present disclosure are defined by the appended claims.

### REFERENCE SIGNS LIST

1 Plasma processing apparatus
10 Chamber
16 Substrate support
22 Electrostatic chuck (ESC)
100 System
102 Robot
104 Image sensor
106 Measurer
108 Controller

1. A system for mounting a component of a substrate processing apparatus on the substrate processing apparatus, the system comprising:
a robot configured to transfer the component to a specified position in the substrate processing apparatus;
an image sensor configured to obtain an image of the component and an upper surface of a substrate support in the substrate processing apparatus;
a measurer configured to calculate, based on the image obtained by the image sensor, at least four distances each between a measurement point of at least two measurement points on the component and a reference point of at least two reference points on the upper surface of the substrate support; and
a controller configured to control the robot and cause the robot to transfer the component to the specified position based on a result of comparison of each of the at least four distances calculated by the measurer with a corresponding reference distance of at least four predetermined reference distances, each of the at least four predetermined reference distances being a distance between a measurement point of the at least two measurement points on the component at the specified position and a reference point of the at least two reference points on the upper surface of the substrate support.

2. The system according to claim 1, wherein
the substrate support includes, as the at least two reference points, a first reference point, a second reference point, and a third reference point, and
the measurer is configured to calculate, as the at least four distances, a first distance between a first measurement point of the at least two measurement points and the first reference point, a second distance between a second measurement point of the at least two measurement points and the second reference point, a third distance between the first measurement point and the third reference point, and a fourth distance between the second measurement point and the third reference point.

3. The system according to claim 2, wherein
the first reference point and the second reference point are on a circle having a center point aligned with a center point of the upper surface of the substrate support, and the first reference point and the second reference point are markers recognizable in the image, and
the measurer is configured to identify, as the third reference point, the center point of the circle identified based on the first reference point and the second reference point.

4. The system according to claim 3, wherein
the first reference point, the second reference point, the third reference point, the first measurement point, and the second measurement point are set such that the first distance and the second distance are equal to each other and such that the third distance and the fourth distance are equal to each other with the component at the specified position.

5. The system according to claim 1, wherein
the substrate support includes, as the at least two reference points, a first reference point and a second reference point, and
the measurer is configured to calculate, as the at least four distances, a distance between a first measurement point of the at least two measurement points and the first reference point, a distance between the first measurement point and the second reference point, a distance between a second measurement point of the at least two measurement points and the first reference point, and a distance between the second measurement point and the second reference point.

6. The system according to claim 1, wherein
the substrate support includes an electrostatic chuck, and
the upper surface of the substrate support is an upper surface of the electrostatic chuck.

7. The system according to claim 6, wherein
the substrate processing apparatus is a plasma processing apparatus including a chamber in which the substrate support is located.

8. The system according to claim 1, further comprising:
another robot configured to move the image sensor,
wherein the controller is configured to control the other robot and cause the other robot to move the image sensor to obtain the image of the component and the upper surface of the substrate support.

9. A method for mounting a component of a substrate processing apparatus on the substrate processing apparatus, the method comprising:
transferring, with a robot, the component to a specified position in the substrate processing apparatus;
obtaining, with an image sensor, an image of the component and an upper surface of a substrate support in the substrate processing apparatus; and
calculating, with a measurer, based on the image obtained by the image sensor, at least four distances each between a measurement point of at least two measurement points on the component and a reference point of at least two reference points on the upper surface of the substrate support,
wherein the transferring includes controlling, with a controller, the robot and causing the robot to transfer the component to the specified position based on a result of comparison of each of the at least four distances calculated by the measurer with a corresponding reference distance of at least four predetermined reference distances, each of the at least four predetermined reference distances being a distance between a measurement point of the at l east two measurement points on the component at the specified position and a reference point of the at least two reference points on the upper surface of the substrate support.
